(19) United States
(12) Patent Application Publication
(10) Pub. No.: US 2026/0044068 A1
(43) Pub. Date: Feb. 12, 2026

(54) APPARATUS AND METHOD FOR CHECKING A COMPONENT, AND LITHOGRAPHY SYSTEM

(71) Applicant: Carl Zeiss SMT GmbH, Oberkochen (DE)

(72) Inventors: MIchael CARL, Aalen (DE); Toralf GRUNER, Aalen-Hofen (DE)

(21) Appl. No.: 19/364,136

(22) Filed: Oct. 21, 2025

Related U.S. Application Data
(63) Continuation of application No. PCT/EP2024/059489, filed on Apr. 8, 2024.

(30) Foreign Application Priority Data
Apr. 24, 2023 (DE) 10 2023 203 731.9

(51) Int. Cl. G03F 1/26; G03F 7/00

(52) U.S. Cl. CPC G03F 1/26; G03F 7/70283; G03F 7/70681; G03F 7/706847; G03F 7/706849

(57) ABSTRACT

An apparatus for checking a component with a periodic structure having substructures arranged on a lattice, the apparatus comprising a measurement radiation source for creating measurement radiation, an optics system, and a camera device. The apparatus further comprises a phase mask device for influencing a phase angle of the measurement radiation and/or an amplitude of the measurement radiation. The phase mask device comprises a dual lattice which is reciprocal to a target shape of the lattice.

### CROSS-REFERENCE TO RELATED APPLICATIONS

The present application is a continuation of, and claims benefit under 35 USC 120 to, international application No. PCT/EP2024/059489, filed Apr. 8, 2024, which claims benefit under 35 USC 119 of German Application No. 10 2023 203 731.9, filed Apr. 24, 2023. The entire disclosure of each of these applications is incorporated by reference herein.

### FIELD

The disclosure relates to an apparatus for checking a component with a periodic structure having substructures arranged on a lattice, at least comprising a measurement radiation source for creating measurement radiation, an optics system and a camera device. The disclosure also relates to a method for checking a component with a periodic structure having substructures arranged on a lattice, with use being made of at least one measurement radiation source for creating measurement radiation, an optics system and a camera device. The disclosure further relates to a lithography system, such as a projection exposure apparatus for producing a semiconductor component, having an illumination system with a radiation source and an optical unit which comprises at least one optical element.

### BACKGROUND

The formation of semiconductor components by etching and/or coating is known.

The formation of NAND memory chips in 3-D construction by etching and/or coating periodically arranged through openings or vias is known. In this context, the vias are frequently realized in deep double layer stacks, for example multiple double layer stacks, or so-called bilayer stacks.

Typically, such semiconductor components use a check for defects or a measurement and/or qualification.

Non-destructive and destructive methods for checking the semiconductor components have been disclosed.

As non-destructive methods, tomographic methods or ptychographic methods or coherent diffraction imaging methods (CDI methods) using x-ray light are known.

However, certain known features of the non-destructive methods known are their potentially complicated implementation and the potentially low throughput obtainable therewith and potentially slow realizable inspection speeds.

For example, the known destructive methods can comprise scanning electron microscopy using focused ion beams (FIB-SEM).

### SUMMARY

The present disclosure seeks to provide an improved an apparatus for checking a component, which can potentially enable an efficient and reliable check of periodic structures. The present disclosure seeks to provide an improved lithography system, which can potentially enables production of efficiently and reliably checked semiconductor components.

In an aspect, the disclosure provides an apparatus for checking a component with a periodic structure having substructures arranged on a lattice. The apparatus comprises a measurement radiation source for creating measurement radiation, an optics system, a camera device, and a phase mask device for influencing a phase angle of the measurement radiation and/or for influencing an amplitude of the measurement radiation. The phase mask device comprises a dual lattice which is reciprocal to a target shape of the lattice.

The apparatus can allow checking of the component with a relatively high throughput or a relatively high inspection speed and can be used within a production line for example.

The apparatus can have a superior accuracy in comparison with certain known inspection methods, which are based on the comparison of conventional intensity images. The apparatus can be suitable for a relatively fast and sufficiently accurate inspection of the component within a production line or for an in-line inspection.

The apparatus can help enable a direct interferometric comparison between a position of a respective individual substructure and its target position. In contrast to a comparison with intensity images captured using a conventional microscopy objective, this can help enables a direct and simultaneous detection of amplitude deviations and phase deviations. For example, a conventional microscopic resolving limit Δx as per Formula (1) can be circumvented as a result.

$$Δ x ∝ \frac{NA}{λ} \qquad ( 1 )$$

An apparatus can be configured to overlay a diffraction image of the lattice and of the corresponding dual or reciprocal dual lattice, which can be virtually punctiform lattices.

Provision can be made for the dual lattice to be arranged such that the diffraction image of the lattice and the dual lattice are overlaid in an imaging pupil. Further, provision can be made for the zeroth order of diffraction of the dual lattice to have a similar efficiency as the complementary orders contributing to the image overall.

Provision can be made for the light source to be configured for a Köhler-type illumination of the component.

In a development of the apparatus according to the disclosure, provision can be made for the phase mask device to have dual substructures arranged on the dual lattice.

The dual substructures can correspond to a target shape of the substructures to be examined.

In a development of the apparatus according to the disclosure, provision can be made for the dual substructures to be at least approximately circular.

Especially when examining or measuring vias, which frequently have a circular target cross section, whereby the substructures to be examined also have circular target cross sections, it can be desirable for the dual substructures to have a circular cross section.

In a development of an apparatus according to the disclosure, provision can be made for the phase mask device to bring about, away from the dual substructures, a phase offset of the measurement radiation of half a wavelength of the measurement radiation vis-à-vis a complement of the dual substructures on the phase mask device.

In a configuration, wherein the phase mask device brings about, away from the dual substructures, a phase offset of the measurement radiation of half a wavelength of the measurement radiation vis-à-vis a complement of the dual substructures and the dual substructures have an at least approximately circular embodiment, a phase mask device arises which is formed as a binary λ/2 phase aperture mask with a carrier in the dual lattice and is given by the expression χ_{G*} in Formula (2).

$${χ}_{{G}^{*}} = \{ \begin{matrix}0 , & k ∈ {G}^{*} * {χ}_{K} \\ \frac{λ}{2} + i ϵ ( k ) , & otherwise\end{matrix} \qquad ( 2 )$$

In Formula (2), χ_{K}: ={k≤ε} specifies a disc of radius ε. Further, the operator * symbolizes mathematical convolution.

Hence, G^{*}*χ_{K} realizes an ε-neighbourhood of the dual lattice. In Formula (2) the dual lattice is denoted as G^{*}. The ε-neighbourhoods can also be referred to as holes.

Here, the phase mask device is the case & (k)=0. Provision can be made for an amplitude mask device with a non-vanishing € (k) as per Formula (2) to also be provided in addition to the phase mask device, the amplitude mask device being used to lower a transmission of the measurement radiation in a region away from the dual substructures or in a complement of the dual substructures on the phase mask device. In this case, ∈(k)≥0 denotes a real absorption coefficient in the complement of the dual substructures.

In a development of the apparatus according to the disclosure, provision can be made for the optics system to comprise at least one Fourier device for performing an optical Fourier transform on the measurement radiation.

By using a Fourier device for performing the optical Fourier transform, the diffraction image of the lattice can be overlaid on the dual lattice in a relatively simple manner.

In a development of the apparatus according to the disclosure, provision can be made for an arrangement device to be provided and configured to accommodate the component in such a way that the periodic structure is arranged in an object plane of the Fourier device.

If the apparatus is configured to arrange the component such that the periodic structure is arranged in the object plane of the Fourier device, then the optical Fourier transform can be implemented relatively reliably and precisely.

The object plane can be arranged perpendicular to an optical axis of the optics system and/or the Fourier device.

For example, the object plane can be arranged in, or coincide with, a focal plane, such as a front focal plane, of the Fourier device.

To this end, it can be desirable for an arrangement device to be provided and configured to accommodate the component.

In a development of the apparatus according to the disclosure, provision can be made for the phase mask device to be arranged in a pupil plane of the Fourier device which is reciprocal to the object plane.

An arrangement of the phase mask device in the pupil plane of the Fourier device can help allow a relatively reliable overlay of the diffraction image of the lattice, subject to an optical Fourier transform by the Fourier device, with the dual lattice on the phase mask device. The phase mask device can be arranged in the imaging pupil of the Fourier device.

In a development of the apparatus according to the disclosure, provision can be made for the Fourier device to comprise a lens and either have a first numerical aperture in order to check the entire periodic structure perpendicularly to the object plane or have a second numerical aperture in order to check only a sectional region of the periodic structure parallel to the object plane.

For example, provision can be made for the first numerical aperture can be smaller than the second numerical aperture.

If a small numerical aperture or a high depth of field is used, then it is possible to detect, in simultaneously averaged fashion, all deviations of the periodic structure of the component along an optical axis or along a depth of the periodic component. The depth of field Δz can be given by Formula (3).

$$Δ z ∝ \frac{λ}{{NA}^{2}} \qquad ( 3 )$$

In Formula (3), λ specifies the wavelength of the measurement radiation and NA specifies the numerical aperture of the Fourier device comprising a microscope objective.

By contrast, if use is made of a very large numerical aperture or a small depth of field (see Formula (3)), then it is possible to analyse sectional planes at a depth of the component along the optical axis.

Provision can be made for the apparatus according to the disclosure to be configured to scan the component at a depth z of the component. The depth z can be oriented along an optical axis for example. By scanning at the depth z, it is possible to interferometrically determine positional deviations and/or other deviations as a function of the depth z.

Provision can be made for the Fourier device to be configured for operation in a first mode of operation, in which the Fourier device has the first numerical aperture, and for operation in a second mode of operation, in which the Fourier device has the second numerical aperture, with the first mode of operation and the second mode of operation not being present at the same time.

In a development of the apparatus according to the disclosure, provision can be made for the Fourier device to comprise an aperture stop which is configured to set the numerical aperture of the Fourier device.

The aperture stop can help enable a simple switchover between the first mode of operation and the second mode of operation.

Setting the numerical aperture or the depth of field, which may be linked as per Formula (3), can be successful relatively simply and reliably by adapting a stop radius of the aperture stop of the Fourier device.

In this case, it can be desirable for the lens of the Fourier device to be designed as a high NA lens. By reducing the stop radius, it is possible in this case to reduce the high initial NA of the lens, whereby there is an increase in the depth of field.

In a development of the apparatus according to the disclosure, provision can be made for a holding device to be provided and configured to displace the phase mask device in the pupil plane, such as in both spatial directions of the pupil plane.

By displacing the phase mask device in the pupil plane, it is possible to minimize influences of optical aberrations on a measurement result of the check of the component.

In a manner analogous to phase shifting known from interferometry, some of the aberrations can be “removed by calibration” by displacing the phase mask device.

Additionally, this enables a more accurate determination of the interference phases of the measurement radiation.

In a development of the apparatus according to the disclosure, provision can be made for the phase mask device to be formed by an etched structuring of a half wavelength coating on a transmittive or transmissive substrate.

If the phase mask is produced by an etched structuring of a λ/2 coating on a transmissive substrate, this can help enable a relatively simple and reliable formation of both the phase mask device and a constant absorptive effect ∈≥0 in the complement of the dual substructures of the phase mask device as per Formula (2).

For example, provision can be made for the transmissive substrate to be part of the optical system and/or an optics design of the apparatus according to the disclosure.

The phase mask device can be formed by transmissive or slightly absorbent glasses which have a structured thickness. The thickness of the glasses can be proportional to the phase effect of the phase mask device given in Formula (2) by ⋅_{G*}. The depth variation used to this end can be achieved by etching processes for example.

In an alternative or in addition, provision can be made for the phase mask device to be formed by a mirror with height structuring. In this case, the height structuring of the mirror can be proportional to the phase effect χ_{G*} as per Formula (2).

In both the embodiment using a glass with a depth structure or a mirror with a height structure, the path difference between the dual substructures and their complement on the phase mask device for the measurement radiation is an optical path length of half a wavelength or λ/2.

Provision can be made for the aberrations caused by the phase mask device or the substrate to be compensated for by the optical system, for example the Fourier device and the lens there.

In an alternative or in addition, provision can be made for a laser to be used to form or drill holes with an optical length of λ/2 in a glass substrate.

In a development of the apparatus according to the disclosure, provision can be made for the phase mask device to be designed to be digitally actuatable and/or transmissive and/or reflective and/or as a microelectronic mechanical system and/or as a spatial light modulator (SLM), for example as a liquid crystal on silicon SLM (LCOS-SLM) and/or as a spatial optical phase modulator.

If a digitally actuatable, transmissive or reflective phase mask device based on MEMS (microelectromechanical system) for example is used, it is possible to set any desired phase effects or any desired dual lattices or G^{*} patterns within the spatial resolution of the MEMS.

In a development of the apparatus according to the disclosure, provision can be made for an imaging device to be provided for imaging the measurement radiation on the camera device.

The imaging device can help enable, such as in a second Fourier step, relatively reliable imaging of the measurement radiation, which carries the information about the component, on a camera device. For example, this can help ensure a high image quality which can enables an optionally digital analysis of the interferograms arising as a result.

In a development of the apparatus according to the disclosure, provision can be made for the Fourier device to comprise a zoom optical unit.

The use of a zoom optical unit can help allow a pupil dimension of the Fourier device and hence an illumination region of the phase mask device to be varied. For example, the dual lattice G^{*} can be scaled as a result.

Together with the zoom optical unit, virtually any desired pattern for the dual lattice or G^{*} pattern can be set using a digitally actuatable and/or transmissive and/or reflective phase mask device and/or the phase mask device designed as a microelectronic mechanical system and/or as a spatial light modulator, for example as a liquid crystal on silicon SLM and/or as a spatial optical phase modulator.

In a development of the apparatus according to the disclosure, provision can be made for the measurement radiation source to be configured to create measurement radiation at different wavelengths and/or for the measurement radiation to be infrared radiation.

If use is made of different wavelengths together with appropriately scaled dual lattices or G^{*} patterns, then it is possible to increase measurement accuracy and/or detection accuracy.

The scaling of the dual lattice or the G^{*} pattern can be implemented here by the above-described zoom lens and/or by changing the phase mask device.

The above-described configuration of the phase mask device as a dual lattice G^{*} can be suitable for the purpose of inspecting NAND memory chips or, more generally, for inspecting G-periodic structures.

Further, if the lens uses infrared light, then the component can be penetrated through its depth by the measurement radiation. For example, NAND stacks can be penetrated through their depth by the measurement radiation in this way.

Methods have been proposed in which the substructures are compared in pairs using differential interference contrast microscopy (DIC microscopy). Compared to the apparatus according to the disclosure, such approaches mean that individual substructures, for example vias, do not represent a good reference as they rigidly deviate from a target shape but may nevertheless be uncritical to the production. However, the DIC signal transports no information as to how relevant the large relative deviation measured is to the practical production. Such issues can be circumvented by an apparatus according to the disclosure.

The apparatus according to the disclosure can be suitable for checking manufactured vias for defects in three dimensions and for qualifying and/or measuring vias.

In a development of the apparatus according to the disclosure, provision can be made for the dual lattice to be designed as a reciprocal of a one-dimensional and/or two-dimensional target shape of the lattice.

The apparatus can be desirable when used to measure a one-dimensional and/or two-dimensional lattice.

For measuring a two-dimensional lattice, the dual lattice can likewise have a two-dimensional, such as extensive, form.

For measuring a one-dimensional lattice, the dual lattice can likewise have a one-dimensional, such as linear, form.

In an aspect, the disclosure provides a method for checking a component with a periodic structure having substructures arranged on a lattice, with use being made of at least one measurement radiation source for creating measurement radiation, at least one optics system, and at least one camera device. Provision is made for a respective deviation of the substructures from a reference substructure to be ascertained by interferometry.

In a method according to the disclosure, a deviation of the periodic structure from a target structure is ascertained by interferometry. In this case, a respective shape of the substructures and their position on the lattice is considered to be a complex-value optical mask.

A method according to the disclosure can be desirable in that the direct interferometric comparison, in contrast to the averaging of intensity images of certain conventional microscopy objectives, allows a direct detection of amplitude deviations and phase deviations and hence a circumvention of a conventional resolution limit.

In the method according to the disclosure, a diffraction image of the lattice and of the corresponding dual or reciprocal dual lattice, which can be virtually punctiform lattices, can be overlaid on one another.

In a development of the method according to the disclosure, provision can be made for the reference substructure to be ascertained by periodic averaging of the periodic structure.

The interferogram made of the object, i.e. the component or the lattice, and the reference substructure, with the reference substructure arising by periodic averaging, can for example be measurable as an intensity image of the form given in Formula (4).

$$I ( β x ) ∝ {\vert obj ( x ) - c {\sum }_{g ∈ G} obj ( x + g ) \vert}^{2} \qquad ( 4 )$$

In Formula (4), G represents the lattice, on the lattice points of which the substructures are arranged, or G can be referred to as the lattice of the substructure positions.

The lattice can have a one-dimensional and/or two-dimensional form.

x describes a location in the object space and β describes an imaging scale of the optical system, and c describes a complex constant, optionally near the inverse of the number of lattice points, with the result that the reference substructure approximately represents periodic averaging.

In a development of the method according to the disclosure, provision can be made for the periodic averaging to be performed by overlaying a diffraction image of the periodic structure with a phase mask device.

In a development, the periodic averaging can be created by the overlay of the diffraction images of the dual lattice G^{*} which is correspondingly dual or is referred to as reciprocal to the lattice G using terminology of crystallography.

An alternative method for recording the interference image I(x) according to Formula (4) can consist in a separate creation of a reference image and a test image, followed by coherently overlaying the reference image and the test image.

In a development of the method according to the disclosure, provision can be made for the measurement radiation to be influenced by the phase mask device by virtue of a phase angle of the measurement radiation within dual substructures, such as circular dual substructures, on a dual lattice which is reciprocal to a target shape of the lattice being offset by half a wavelength of the measurement radiation vis-à-vis a complement of the dual substructures on the phase mask device.

In this case, the phase mask device acts on the measurement radiation in the style of a binary λ/2 phase aperture mask, in which the dual substructures are arranged on a carrier which is represented by the dual lattice G*.

It can be desirable for the zeroth order of diffraction of the phase mask device to have a similar diffraction efficiency to the sum of the higher, imaged orders of diffraction such that object and reference, i.e. an image of the component and an image of the phase mask device, which are described by the two summands in Formula (4), have similar intensities, at least in a mean value over the location x. To this end, the complement of the perforated mask or the dual substructures on the phase mask device can have an absorption coefficient ∈(k)≥0 as per Formula 2.

In this case, the region of the phase mask device away from the dual substructures, i.e. a complement of the dual substructures, acts at least approximately as a conventional pupil and creates the first term of Formula (4) optically, apart from a location-constant phase, while a reference image or the image of the phase mask device, which is given by the second term in Formula (4), is created apart from a constant phase by the lattice of the dual substructures.

Provision can be made for an intensity pattern of the measurement radiation on the camera device to be ascertained by virtue of the measurement radiation being imaged on the camera device by an imaging device following the overlay of the diffraction image of the periodic structure with the phase mask device.

In a development of the method according to the disclosure, provision can be made for a focal length of the Fourier device to be varied by a zoom optical unit.

This can help allow the realization of dual lattices G* for different object lattice structures or for different lattices G without exchanging the phase mask device or the phase aperture mask.

Moreover, slight wavelength adaptations can be carried out by way of the zoom optical unit provided the phase offset in the phase mask device or the phase aperture mask remains at least approximately at half a wavelength of the measurement radiation.

If the above-described λ/2 phase aperture mask is imaged on the camera device, then the intensity image given by Formula (4) arises on the camera device and is rendered measurable by the camera device. This facilitates a digital analysis of the intensity distribution. On the camera device, the intensity distribution arises as the norm square of a complex-linear mapping S which, apart from scaling but with consideration of a diffraction at a pupil edge, is given by Formula (5).

$$S ( obj ) ( β x ) := {F}_{{f}^{′}}^{- 1} ( {χ}_{NA} \cdot exp ( i {χ}_{{G}^{*}} ) \cdot {F}_{f} obj ) ( x ) \qquad ( 5 )$$

In Formula (5) specified above, χ_{G*} describes the perforated mask or the phase mask device as per Formula (2). According to Formula (5), the periodic structure of the component is given as a complex-value optical mask obj. Fr denotes an operator of a Fourier transform with focal length f, which is given by Formula (5a).

$${F}_{f} ( obj ) ( {x}_{k} ) := \int exp ( - i \frac{〈 {x}_{k} , x 〉}{f} \cdot \frac{2 π}{λ} ) obj ( x ) {d}^{2} x \qquad ( 5 a )$$

In Formula (5a), the vector specifies two-dimensional xx spatial coordinates in a collimated region of the measurement radiation. Physical pupil coordinates k, which describe a beam direction of the measurement radiation and which are normalized to 21/1, are described by Formula (5b).

$$k := \frac{{x}_{k}}{f} \frac{2 π}{λ} \qquad ( 5 b )$$

As a function of k, F_{f}obj is thus a conventional Fourier transform of obj.

A characteristic function of the pupil-restricting stop is given in Formula (6).

$${χ}_{NA} ( k ) = 1 for \vert k \vert < NA \cdot \frac{2 π}{λ} ; 0 otherwise \qquad ( 6 )$$

Further, f′ describes a focal length of a second Fourier step, for example an effect of the imaging device, with the result that the mapping S contains the imaging scale

$$β := \frac{{f}^{′}}{f}$$

The above-described characteristic function for restricting the pupil represents a low-pass filter in the present case. The characteristic function for restricting the F⁻¹χ_{NA} pupil can be expressed as a convolution of the signal of the measurement radiation with an amplitude point spread function. Such a convolution can be observable as a blurring of the signal for example, especially in the form of Airy discs.

However, phase information in the difference signal of the measurement radiation can be preserved a priori in the intensity signal according to Formula (5).

The intensity distribution given in Formula (5) can be further rewritten mathematically, whereby the equation according to Formula (7) arises approximately.

$$S ( obj ) ( β x ) \approx ( {F}_{{f}^{′}}^{- 1} {χ}_{NA} * \{ - t β obj + {t}^{′} {F}_{{f}^{′}}^{- 1} {δ}_{G *} {F}_{f} obj \} ) ( x ) \qquad ( 7 )$$

In Formula (7), t, t′ denote positive constants in x, which depend for example on a diameter of the dual substructures and on the absorption coefficient of the phase mask device in the complement of the dual substructures. Further, δ_{G*} denotes a Dirac delta function on the carrier of the dual lattice G^{*.} The expression given in Formula (7) can be rewritten approximately as the expression given in Formula (8) using Fourier's theorem.

$$S ( obj ) ( β x ) \approx β ( {F}_{{f}^{′}}^{- 1} {χ}_{NA} * \{ - t obj + {t}^{′} {δ}_{G *} * obj \} ) ( x ) \qquad ( 8 )$$

In turn, the expression as per Formula (8) can be rewritten as the expression for the mapping S given in Formula (9). In this case, the expressions on the right-hand side of Formula (8) and Formula (9) are mathematically identical.

$$S ( obj ) ( β x ) \approx β ( {F}_{{f}^{′}}^{- 1} {χ}_{NA} * \{ - t obj + {t}^{′} {\sum }_{g ∈ G} obj ( x + g ) \} ) ( x ) \qquad ( 9 )$$

The norm square of S thus approximates the interferogram according to the disclosure as per Formula (4).

In a manner analogous to phase shifting known from interferometry, some of the aberrations can additionally be “removed by calibration” by displacing the phase mask device. Further, a partial calibration of aberrations and hence a more accurate determination of the interference phases of the measurement radiation is made possible. The phase of the measurement radiation in t′(ϵ) in a difference signal S (see Formulas (7)-(9)) is varied by an offset of the phase mask device.

Provision can be made for the Fourier device to comprise a neutral density filter, such as a neutral density filter arranged in a pupil plane.

The neutral density filter can have the shape of a Gaussian profile as per Formula (10).

$${χ}_{NA} ( k ) ∝ exp ( - \frac{{k}^{2}}{{NA}_{Gauss}^{2}} ) \qquad ( 10 )$$

In Formula (10), NA²_{Gauss} denotes a numerical aperture under the assumption of a Gaussian distribution.

What can be achieved by the neutral density filter designed as per Formula (10) is F^{-t}χ_{NA} that the expression

itself is Gaussian and for example a positive real, whereby the interference signal of the measurement radiation is only Gauss averaged but not phase modulated by the neutral density filter.

Alternatively, the neutral density filter can be integrated directly in the phase aperture mask or the phase mask device by way of the absorption coefficient ∈(k) in Formula (2).

In a development of the method according to the disclosure, provision can be made for the diffraction image of the periodic structure and the phase mask device to be overlaid in a pupil plane of the Fourier device.

The Fourier device can be designed as a Fourier lens. For example, the Fourier device can be designed as a catadioptric lens element, as for example known from document U.S. Pat. No. 7,639,419 B2, for example from FIG. 16 therein, and/or as part of a lithography lens, as for example known from document US 2018/0031815 A1, for example from FIG. 1 therein.

It can be desirable for provision to be made for the Fourier device to be aberration optimized. For example, it can be desirable for the Fourier device to have only small phase gradients such that distortions and hence a mismatch between the phase mask device and the periodic structure can be avoided.

In this case, aberrations may lead to small phase modulations, with aberrations in Formula (5) arising as a result of the following applying:

$$arg ( {χ}_{NA} ) \neq 0 for \vert k \vert < NA \cdot \frac{2 π}{λ}$$

In a development of the method according to the disclosure, provision can be made for a plurality of interferograms to be recorded, with the phase mask device being displaced to a different location in the pupil plane for each interferogram.

Some of the above-described aberrations can be removed by calibration by way of phase shifting. As a result of an offset of the perforated mask, the phase of t′ (E) in the difference signal S can be varied as per Formula (9), which in a manner analogous to phase shifting in interferometry allows a more accurate determination of the interference phases.

In a development of the method according to the disclosure, provision can be made for different wavelengths of the measurement radiation to be used, with optionally the dual lattice being scaled in accordance with the wavelength of the measurement radiation used.

Measurement accuracy can be increased further by varying the wavelength.

In a development of the method according to the disclosure, provision can be made for the scaling of the dual lattice
to be brought about by a change of the phase mask device and/or
to be brought about by the Fourier device which can comprise a zoom optical unit, with a pupil size and/or an illumination region of the phase mask device being varied.

By varying the phase mask device and/or a focal length of the Fourier device, it is possible to scale the dual lattice for examplely simple and reliable fashion.

The zoom optical unit allows optical properties of the Fourier device to be varied relatively quickly. This can increase a throughput of the method.

In a development of the method according to the disclosure, provision can be made for the component to be additionally checked using a method for measuring an optically critical dimension, the intensity distribution of which is simulated with the aid of a parameterized model of the component.

In addition to the above-described developments, the method according to the disclosure can also be combined with methods for measuring the optically critical dimension (OCD methods). In OCD methods, the mapping S to be expected as per Formula (9) is simulated with the aid of a parameterized model of the component. In the process, the parameters of the parameterized model are optimized such that they fit to a measurement result, i.e. to the actual measured mapping S as per Formula (9).

This can result in an accuracy of a parameter reconstruction of the parameterized model which can be increased a priori by way of the inclusion according to the disclosure of the phase information of the measurement radiation.

In a development of the method according to the disclosure, provision can be made for a NAND memory chip with periodically arranged vias to be checked as the component.

The method can be suitable for checking a memory chip comprising a NOT-AND logic gate (NAND memory chip). The vias arranged periodically in such NAND memory chips, as a periodic structure, can be checked in reliable and quick fashion using a method according to the disclosure.

It can also be desirable for a parameterized model of the NAND memory chip to be simulated within the scope of the combination with OCD methods.

Provision can be made for the method according to the disclosure to be combined with methods of differential interference contrast microscopy.

Methods of differential interference contrast microscopy for measuring components are described in DE 10 2018 217 115 A1, for example. The methods according to DE 10 2018 217 115 A1 may be suitable for example for implementing mixed forms with the method according to the disclosure.

In a development of the method according to the disclosure, provision can be made for the dual lattice to be designed as a reciprocal of a one-dimensional and/or two-dimensional target shape of the lattice.

In an aspect, the disclosure provides a lithography system, such as a projection exposure apparatus for producing a semiconductor component, which comprises an illumination system with a radiation source and an optical unit which comprises at least one optical element. The lithography system includes an above-described apparatus according to the disclosure for checking a component, such as for checking the semiconductor component. In an alternative or in addition, provision is made for the lithography system to be configured to carry out a method for checking a component, such as a semiconductor component, according to the disclosure.

Thus, an apparatus according to the disclosure for checking a component is provided in the lithography system according to the disclosure as a part of the lithography system, and can be configured to check the semiconductor component to be produced by the lithography system. In an alternative or in addition, the lithography system is configured to carry out the above-described method according to the disclosure for checking a component, with the lithography system optionally being configured to perform the method according to the disclosure for checking the semiconductor component to be produced by the lithography system.

Provision can be made for, in the lithography system according to the disclosure, the apparatus for checking the semiconductor component to be spatially separate from the location where the semiconductor component is exposed and/or for the method for checking the semiconductor component to be produced by the lithography system to be performed spatially separate from the location where the semiconductor component is exposed.

As a result of the integrated quality control, the lithography system according to the disclosure can help enable the efficient and reliable production of high-quality semiconductor components. In the present case, the method according to the disclosure and the apparatus according to the disclosure are used to check a component presently provided by the semiconductor component to be produced.

In a development of the lithography system according to the disclosure, provision can be made for the latter to be configured to produce and check a semiconductor component designed as a NAND memory chip with periodically arranged vias.

In general terms, it can be desirable for a lithography system according to the disclosure to be configured to produce structures imaged on a wafer and check these with regards to possible malformations.

The component to be checked according to the disclosure can be a semiconductor component, for example a semiconductor component produced by a or the lithography system. The semiconductor component can be a NAND memory chip.

Features described in conjunction with one of the subjects of the disclosure, specifically given by the apparatus according to the disclosure, the method according to the disclosure, or the lithography system according to the disclosure, are also implementable for the other subjects of the disclosure. Likewise, features specified in conjunction with one of the subjects of the disclosure can also be understood in relation to the other subjects of the disclosure.

Additionally, it should be noted that terms such as “comprising”, “having”, or “with” do not exclude other features or steps. Furthermore, terms such as “a (n)” or “the” which indicate single steps or features do not exclude a plurality of features or steps—and vice versa.

It should be noted that labels such as “first” or “second”, etc. are used predominantly for reasons of distinguishability between respective apparatus or method features and are not necessarily intended to indicate that features involve one another or are related to one another.

Moreover, at this point it is disclosed that the interferometer apparatus according to the disclosure and/or the method according to the disclosure is also suitable for measuring a surface of any desired element. For example, the surface can be a surface of a component from the automotive industry. In this respect, the applicant reserves the right to file a divisional application in which the feature “optical element” has been replaced by the feature “element”.

Exemplary embodiments of the disclosure will be described in detail hereinbelow with reference to the drawing.

The figures each show certain exemplary embodiments in which individual features of the present disclosure are illustrated in combination with one another. Features of an exemplary embodiment are also implementable independently of the other features of the same exemplary embodiment, and may readily be combined accordingly by a person skilled in the art to form further viable combinations and sub-combinations with features of other exemplary embodiments.

### BRIEF DESCRIPTION OF THE DRAWINGS

In the drawings, functionally identical elements are given the same reference signs. In the drawings:

FIG. 1 shows a meridional section of an EUV projection exposure apparatus;

FIG. 2 shows a DUV projection exposure apparatus;

FIG. 3 shows a schematic illustration of a possible embodiment of an apparatus according to the disclosure for checking a component;

FIG. 4 shows a schematic illustration of a possible embodiment of the phase mask device;

FIG. 5 shows a block diagram-type illustration of a possible embodiment of a method according to the disclosure for checking a component; and

FIG. 6 shows a schematic illustration of a possible embodiment of a NAND memory chip to be checked.

### DETAILED DESCRIPTION

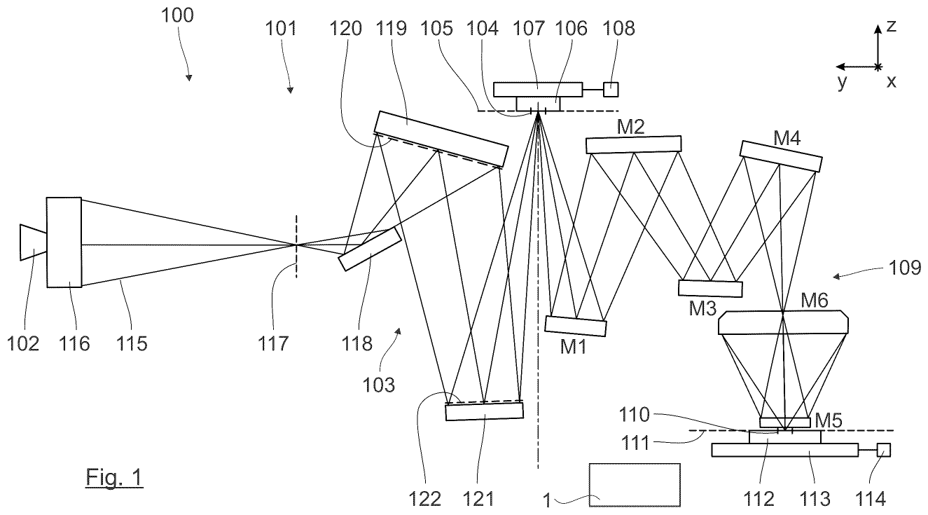

With reference to FIG. 1, certain components of a microlithographic EUV projection exposure apparatus 100 as an example of a lithography system are initially described below in exemplary fashion. The description of the basic structure of the EUV projection exposure apparatus 100 and of the component parts thereof should not be interpreted restrictively here.

An illumination system 101 of the EUV projection exposure apparatus 100 comprises, besides a radiation source 102, an illumination optical unit 103 for the illumination of an object field 104 in an object plane 105. What is exposed here is a reticle 106 arranged in the object field 104. The reticle 106 is held by a reticle holder 107. The reticle holder 107 is displaceable, for example in a scanning direction, by way of a reticle displacement drive 108.

In FIG. 1, a Cartesian xyz-coordinate system is plotted to aid the explanation. The x-direction runs perpendicularly into the plane of the drawing. The y-direction runs horizontally, and the z-direction runs vertically. In FIG. 1, the scanning direction runs along the y-direction. The z-direction runs perpendicularly to the object plane 105.

The EUV projection exposure apparatus 100 comprises a projection optical unit 109. The projection optical unit 109 serves for imaging the object field 104 into an image field 110 in an image plane 111. The image plane 111 extends parallel to the object plane 105. Alternatively, an angle that differs from 0° between the object plane 105 and the image plane 111 is also possible.

A structure on the reticle 106 is imaged onto a light-sensitive layer of a wafer 112 arranged in the region of the image field 110 in the image plane 111. The wafer 112 is held by a wafer holder 113. The wafer holder 113 is displaceable, for example along the y-direction, by way of a wafer displacement drive 114. The displacement on the one hand of the reticle 106 by way of the reticle displacement drive 108 and on the other hand of the wafer 112 by way of the wafer displacement drive 114 may take place in such a way as to be synchronized with one another.

The radiation source 102 is an EUV radiation source. The radiation source 102 emits EUV radiation 115, for example, which is also referred to as used radiation or illumination radiation below. For example, the used radiation 115 has a wavelength in the range between 5 nm and 30 nm. The radiation source 102 can be a plasma source, for example an LPP source (“laser produced plasma”) or a GDPP source (“gas discharged produced plasma”). It can also be a synchrotron-based radiation source. The radiation source 102 can be a free electron laser (FEL).

The illumination radiation 115 emanating from the radiation source 102 is focused by a collector 116. The collector 116 may be a collector with one or more ellipsoidal and/or hyperboloid reflection surfaces. The at least one reflection surface of the collector 116 can be impinged upon by the illumination radiation 115 with grazing incidence (GI), i.e. with angles of incidence greater than 45°, or with normal incidence (NI), i.e. with angles of incidence less than 45°. The collector 116 can be structured and/or coated, firstly, for optimizing its reflectivity for the used radiation 115 and, secondly, for suppressing extraneous light.

Downstream of the collector 116, the illumination radiation 115 propagates through an intermediate focus in an intermediate focal plane 117. The intermediate focal plane 117 may represent a separation between a radiation source module, having the radiation source 102 and the collector 116, and the illumination optical unit 103.

The illumination optical unit 103 comprises a deflection mirror 118 and, downstream thereof in the beam path, a first facet mirror 119. The deflection mirror 118 may be a plane deflection mirror or, alternatively, a mirror with a beam-influencing effect that goes beyond the pure deflection effect. In an alternative or in addition, the deflection mirror 118 may be designed as a spectral filter that separates a used light wavelength of the illumination radiation 115 from extraneous light at a different wavelength. If the first facet mirror 119 is arranged in a plane of the illumination optical unit 103 that is optically conjugate to the object plane 105 as a field plane, it is also referred to as a field facet mirror. The first facet mirror 119 comprises a plurality of individual first facets 120, which are also referred to below as field facets. Only a few of these facets 120 are illustrated in FIG. 1 in exemplary fashion.

The first facets 120 can be embodied in the form of macroscopic facets, for example in the form of rectangular facets or in the form of facets with an arcuate peripheral contour or a peripheral contour of part of a circle. The first facets 120 may be embodied as plane facets or alternatively as convexly or concavely curved facets.

As is known for example from DE 10 2008 009 600 A1, the first facets 120 themselves can also each be composed of a multiplicity of individual mirrors, for example a multiplicity of micromirrors. For example, the first facet mirror 119 can be in the form of a microelectromechanical system (MEMS system). For details, reference is made to DE 10 2008 009 600 A1.

The illumination radiation 115 travels horizontally, i.e. along the y-direction, between the collector 116 and the deflection mirror 118.

In the beam path of the illumination optical unit 103, a second facet mirror 121 is arranged downstream of the first facet mirror 119. Provided the second facet mirror 121 is arranged in a pupil plane of the illumination optical unit 103, it is also referred to as a pupil facet mirror. The second facet mirror 121 can also be arranged at a distance from a pupil plane of the illumination optical unit 103. In this case, the combination of the first facet mirror 119 and the second facet mirror 121 is also referred to as a specular reflector. Specular reflectors are known from US 2006/0132747 A1, EP 1 614 008 B1 and U.S. Pat. No. 6,573,978.

The second facet mirror 121 comprises a plurality of second facets 122. In the case of a pupil facet mirror, the second facets 122 are also referred to as pupil facets.

The second facets 122 may likewise be macroscopic facets, which may for example have a round, rectangular or else hexagonal periphery, or may alternatively be facets composed of micromirrors. In this regard, reference is likewise made to DE 10 2008 009 600 A1.

The second facets 122 can have plane or, alternatively, convexly or concavely curved reflection surfaces.

The illumination optical unit 103 consequently forms a doubly faceted system. This basic principle is also referred to as fly's eye integrator.

It may be desirable to arrange the second facet mirror 121 not exactly in a plane that is optically conjugate to a pupil plane of the projection optical unit 109.

With the aid of the second facet mirror 121, the individual first facets 120 are imaged into the object field 104. The second facet mirror 121 is the last beam-shaping mirror or else indeed the last mirror for the illumination radiation 115 in the beam path upstream of the object field 104.

In a further embodiment (not illustrated) of the illumination optical unit 103, a transfer optical unit may be arranged in the beam path between the second facet mirror 121 and the object field 104, and contributes for example to the imaging of the first facets 120 into the object field 104. The transfer optical unit may have exactly one mirror or, alternatively, also two or more mirrors, which are arranged in succession in the beam path of the illumination optical unit 103. For example, the transfer optical unit can comprise one or two mirrors for normal incidence (NI mirror, “normal incidence” mirror) and/or one or two mirrors for grazing incidence (GI mirror, “grazing incidence” mirror).

In the embodiment shown in FIG. 1, the illumination optical unit 103 comprises exactly three mirrors downstream of the collector 116, specifically the deflection mirror 118, the field facet mirror 119 and the pupil facet mirror 121.

In a further embodiment of the illumination optical unit 103, the deflection mirror 118 can also be omitted, and so the illumination optical unit 103 can then have exactly two mirrors downstream of the collector 116, specifically the first facet mirror 119 and the second facet mirror 121.

The imaging of the first facets 120 into the object plane 105 via the second facets 122 or using the second facets 122 and a transfer optical unit is routinely only approximate imaging.

The projection optical unit 109 comprises a plurality of mirrors Mi, which are numbered in accordance with their arrangement in the beam path of the EUV projection exposure apparatus 100.

In the example illustrated in FIG. 1, the projection optical unit 109 comprises six mirrors M1 to M6. Alternatives with four, eight, ten, twelve or any other number of mirrors Mi are likewise possible. The second-last mirror M5 and the last mirror M6 each have a through opening for the illumination radiation 115. The projection optical unit 109 is a doubly obscured optical unit. The projection optical unit 109 has an image-side numerical aperture which is greater than 0.5 and which can also be greater than 0.6 and which, for example, can be 0.7 or 0.75.

Reflection surfaces of the mirrors Mi can be in the form of free-form surfaces without an axis of rotational symmetry. Alternatively, the reflection surfaces of the mirrors Mi can be designed as aspherical surfaces with exactly one axis of rotational symmetry of the reflection surface shape. Just like the mirrors of the illumination optical unit 103, the mirrors Mi may have highly reflective coatings for the illumination radiation 115. These coatings may be in the form of multi-layer coatings, for example with alternating layers of molybdenum and silicon.

The projection optical unit 109 has a large object-image offset in the y-direction between a y-coordinate of a centre of the object field 104 and a y-coordinate of the centre of the image field 110. In the y-direction, this object-image offset can be of approximately the same magnitude as a z-distance between the object plane 105 and the image plane 111.

The projection optical unit 109 may for example have an anamorphic form. For example, it has different imaging scales βx, βy in the x- and y-directions. The two imaging scales βx, βy of the projection optical unit 109 can be (βx, βy)=(+/−0.25, +/−0.125). A positive imaging scale β means imaging without image inversion. A negative sign for the imaging scale β means imaging with image inversion.

The projection optical unit 109 consequently leads to a reduction in size with a ratio of 4:1 in the x-direction, i.e. in a direction perpendicular to the scanning direction.

The projection optical unit 109 leads to a reduction in size of 8:1 in the y-direction, i.e. in the scanning direction.

Other imaging scales are likewise possible. Imaging scales with the same signs and the same absolute values in the x-direction and y-direction, for example with absolute values of 0.125 or 0.25, are also possible.

The number of intermediate image planes in the x-direction and in the y-direction in the beam path between the object field 104 and the image field 110 may be the same or may be different depending on the design of the projection optical unit 109. Examples of projection optical units with different numbers of such intermediate images in the x- and y-directions are known from US 2018/0074303 A1.

One of the pupil facets 122 in each case is assigned to exactly one of the field facets 120, in each case to form an illumination channel for illuminating the object field 104. For example, this can produce illumination according to the Köhler principle. The far field is deconstructed into a multiplicity of object fields 104 using the field facets 120. The field facets 120 create a plurality of images of the intermediate focus on the pupil facets 122 respectively assigned thereto.

The field facets 120 are each imaged by an assigned pupil facet 122 onto the reticle 106 in a manner overlaid on one another in order to illuminate the object field 104. The illumination of the object field 104 is for example as homogeneous as possible. It can have a uniformity error of less than 2%. Field uniformity can be attained by overlaying different illumination channels.

The illumination of the entrance pupil of the projection optical unit 109 can be defined geometrically by way of an arrangement of the pupil facets. The intensity distribution in the entrance pupil of the projection optical unit 109 can be set by selecting the illumination channels, for example the subset of the pupil facets that guide light. This intensity distribution is also referred to as illumination setting.

A likewise preferred pupil uniformity in the region of portions of an illumination pupil of the illumination optical unit 103 that are illuminated in a defined way can be achieved by a redistribution of the illumination channels.

Further aspects and details of the illumination of the object field 104 and for example of the entrance pupil of the projection optical unit 109 are described below.

The projection optical unit 109 may have a homocentric entrance pupil for example. The latter can be accessible. It can also be inaccessible.

The entrance pupil of the projection optical unit 109 generally cannot be illuminated exactly via the pupil facet mirror 121. The aperture rays often do not intersect at a single point in the event of imaging the projection optical unit 109, which telecentrically images the centre of the pupil facet mirror 121 onto the wafer 112. However, it is possible to find a surface area in which the spacing of the aperture rays, which is determined in pairs, becomes minimal. This surface area represents the entrance pupil or a surface area in real space that is conjugate thereto. For example, this surface area exhibits a finite curvature.

It may be the case that the projection optical unit 109 has different positions of the entrance pupil for the tangential beam path and for the sagittal beam path. In this case, an imaging element, for example an optical component of the transfer optical unit, should be provided between the second facet mirror 121 and the reticle 106. With the aid of this optical component, it is possible to take account of the different pose of the tangential entrance pupil and the sagittal entrance pupil.

In the arrangement of the components of the illumination optical unit 103 illustrated in FIG. 1, the pupil facet mirror 121 is arranged in an area conjugate to the entrance pupil of the projection optical unit 109. The first field facet mirror 119 is arranged so as to be tilted in relation to the object plane 105. The first facet mirror 119 is arranged so as to be tilted in relation to an arrangement plane defined by the deflection mirror 118.

The first facet mirror 119 is arranged so as to be tilted in relation to an arrangement plane defined by the second facet mirror 121.

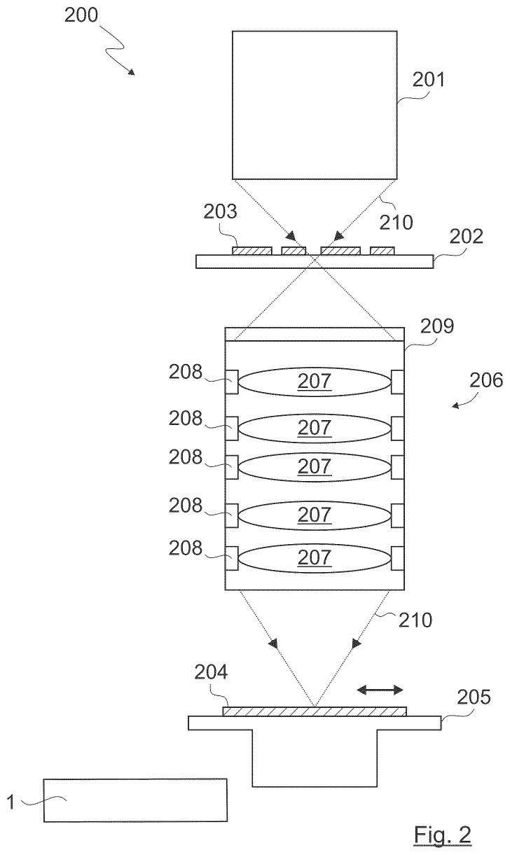

FIG. 2 shows an exemplary DUV projection exposure apparatus 200. The DUV projection exposure apparatus 200 comprises an illumination system 201, a device known as a reticle stage 202 for receiving and exactly positioning a reticle 203 by which the later structures on a wafer 204 are determined, a wafer holder 205 for holding, moving, and exactly positioning the wafer 204, and an imaging unit, specifically a projection optical unit 206, with a plurality of optical elements, for example lens elements 207, which are held by way of mounts 208 in a lens housing 209 of the projection optical unit 206.

As an alternative or in addition to the lens elements 207 illustrated, provision can be made of various refractive, diffractive, and/or reflective optical elements, inter alia also mirrors, prisms, terminating plates, and the like.

The basic functional principle of the DUV projection exposure apparatus 200 makes provision for the structures introduced into the reticle 203 to be imaged onto the wafer 204.

The illumination system 201 provides a projection beam 210 in the form of electromagnetic radiation, which is used for the imaging of the reticle 203 onto the wafer 204. The source used for this radiation may be a laser, a plasma source, or the like. The radiation is shaped in the illumination system 201 via optical elements such that the projection beam 210 has the desired properties with regard to diameter, polarization, shape of the wavefront, and the like when it is incident on the reticle 203.

An image of the reticle 203 is created using the projection beam 210 and transferred from the projection optical unit 206 onto the wafer 204 in an appropriately reduced form. In this case, the reticle 203 and the wafer 204 can be moved synchronously, so that regions of the reticle 203 are imaged onto corresponding regions of the wafer 204 virtually continuously during what is called a scanning operation.

An air gap between the last lens element 207 and the wafer 204 can optionally be replaced by a liquid medium which has a refractive index of greater than 1.0. The liquid medium can be high-purity water, for example. Such a set-up is also referred to as immersion lithography and has an increased photolithographic resolution.

The use of the disclosure is not restricted to use in projection exposure apparatuses 100, 200, for example also not with the described set-up. The disclosure is suitable for any desired lithography systems or microlithography systems, but for example for projection exposure apparatuses having the described set-up. The disclosure is also suitable for EUV projection exposure apparatuses which have a smaller image-side numerical aperture than those described in the context of FIG. 1, and have no obscured mirror M5 and/or M6. For example, the disclosure is also suitable for EUV projection exposure apparatuses which have an image-side numerical aperture from 0.25 to 0.5, such as 0.3 to 0.4, for example 0.33. The disclosure and the following exemplary embodiments should also not be understood as being restricted to a specific design.

The figures that follow illustrate the disclosure merely by way of example and in highly schematized form.

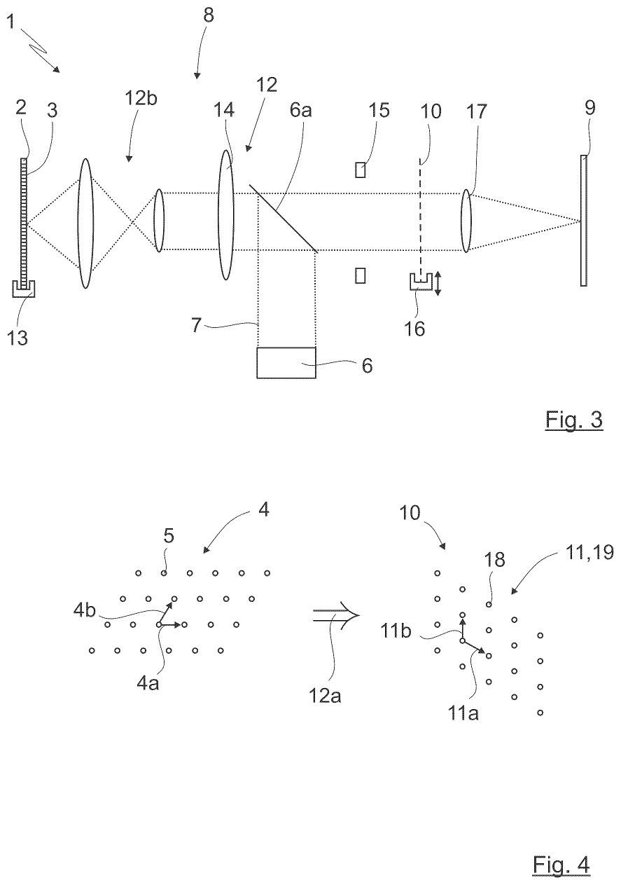

FIG. 3 shows a schematic illustration of a possible embodiment of an apparatus 1 for checking a component 2.

The apparatus 1 serves to check the component 2 with a periodic structure 3, which comprises substructures 5 arranged on a lattice 4. The apparatus 1 comprises at least one measurement radiation source 6 for creating measurement radiation 7, an optics system 8 and a camera device 9. The apparatus 1 also contains a phase mask device 10 for influencing a phase angle of the measurement radiation 7, the phase mask device having a dual lattice 11 which is reciprocal to a target shape of the lattice 4.

The measurement radiation source 6 can be configured to form a Köhler-type illumination of the component 2.

Further, a beam splitter device 6b for input coupling the measurement radiation 7 into the optics system 8 can be provided. A reflected light illumination of the component 2, as depicted in FIG. 3, can be desirable for a component 2 to be examined which is not transmissive but instead reflective for the measurement radiation 7.

In the exemplary embodiment depicted in FIG. 3, the optics system 8 can comprise at least one Fourier device 12 for performing the optical Fourier transform on the measurement radiation 7.

In the exemplary embodiment according to FIG. 3, an arrangement device 13 can also be present and configured to accommodate the component 2 in such a way that the periodic structure 3 is arranged in an object plane of the Fourier device 12.

In the exemplary embodiment depicted in FIG. 3, the phase mask device 10 can be arranged in a pupil plane of the Fourier device 12 reciprocal to the object plane.

In the exemplary embodiment of the apparatus 1 according to FIG. 3, the Fourier device 12 can comprise a lens 14.

Further, the Fourier device 12 either has a first numerical aperture in order to check the entire periodic structure 3 perpendicular to the object plane along an optical axis of the measurement radiation 7 and a depth extent of the component 2.

Alternatively, the Fourier device 12 has a second numerical aperture in order to check only a sectional region of the periodic structure 3 parallel to the object plane.

In this case, the first numerical aperture can be smaller than the second numerical aperture.

In order to change between different numerical apertures, the apparatus 1 in the exemplary embodiment according to FIG. 3 can provide for the Fourier device 12 to comprise an aperture stop 15 which is configured to set the numerical aperture of the Fourier device 12.

At a given time, the Fourier device 12 has either the first or the second numerical aperture. However, the aperture stop 15 allows simple switching between the numerical apertures at different times.

In the exemplary embodiment of the apparatus 1 depicted in FIG. 3, a holding device 16 can be provided and configured to displace the phase mask device 10 in the pupil plane, such as in both spatial directions of the pupil plane. In FIG. 3, the displaceability is epitomized by a double-headed arrow.

The exemplary embodiment of the apparatus 1 depicted in FIG. 3 also contains an imaging device 17 for imaging the measurement radiation 7 onto the camera device 9. In the exemplary embodiment, the imaging device 17 is embodied as part of the optics system 8.

In the exemplary embodiment according to FIG. 3, the Fourier device 12 can comprise a zoom optical unit 12b.

In the exemplary embodiment depicted in FIG. 3, the measurement radiation source 6 can be configured to create measurement radiation 7 at different wavelengths. In an alternative or in addition, provision can be made for the measurement radiation 7 to be infrared radiation.

Alternatively, the beam splitter device 6a can also be arranged between the component 2 and the zoom optical unit 12b.

The dual lattice 11 can be designed as a reciprocal of a one-dimensional and/or two-dimensional target shape of the lattice 4.

FIG. 4 shows a schematic illustration of a possible embodiment of the phase mask device 10.

In the exemplary embodiment depicted in FIG. 4, the phase mask device can comprise dual substructures 18 arranged on the dual lattice 11.

In the exemplary embodiment depicted in FIG. 4, the lattice 4 has lattice vectors 4a, 4b. The dual lattice 11 has dual lattice vectors 11a, 11b.

Further, in FIG. 4, the effect of a Fourier transform is epitomized by an arrow 12a.

Up to scaling, the dual lattice 11 or G* reciprocal to the lattice 4 or G is given by the inverse. Thus, the following applies: GG*=2πE, where E is an identity matrix. In the case of one-dimensional phase lattices, G and G* for example are reciprocal lattice constants. Alternatively, GG* can also be an integer multiple of 2πE.

Further, in the exemplary embodiment of the phase mask device 10 according to FIG. 4, the dual substructures 18 can be at least approximately circular.

Moreover, away from the dual substructures 18, i.e. in a complement of the dual substructures 18, the phase mask device 10 in the exemplary embodiment according to FIG. 4 brings about a phase offset of the measurement radiation 7 of half a wavelength of the measurement radiation 7 vis-à-vis the dual substructures 18.

In the exemplary embodiments according to FIGS. 3 and 4, the phase mask device 10 can be formed by an etched structuring of a half-wavelength coating (λ/2) on a transmissive substrate.

In an exemplary embodiment (not depicted), provision can be made for the phase mask device 10 to be designed to be digitally actuatable and/or transmittive or transmissive and/or reflective and/or as a microelectronic mechanical system and/or as a spatial light modulator (SLM), for example as a liquid crystal on silicon SLM (LCOS-SLM) and/or as a spatial optical phase modulator.

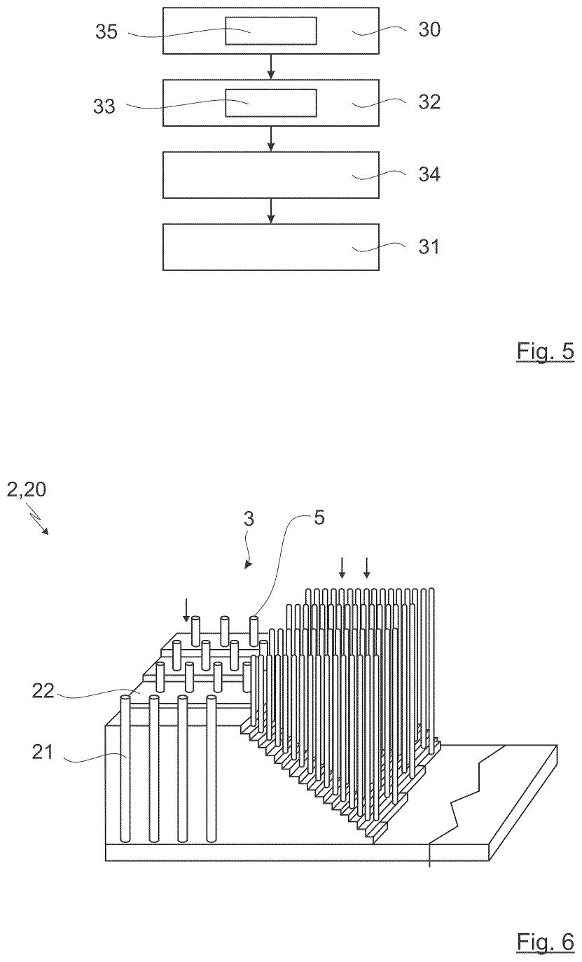

FIG. 5 shows a block diagram-type illustration of a possible embodiment of a method for checking the component 2.

In the method for checking the component 2 with the periodic structure 3, which has substructures 5 arranged on the lattice 4, the measurement radiation source 6 for creating the measurement radiation 7 is used in a creation block 30. The optics system 8 and the camera device 9 are also used. In a deviation block 31, a respective deviation of the substructures 5 from a reference substructure is ascertained by interferometry.

In the exemplary embodiment depicted in FIG. 5, an averaging block 32 can be provided, in which the reference structure is ascertained by periodic averaging of the periodic structure 3.

Within the scope of the averaging block 32, periodic averaging can be performed by overlaying a diffraction image 19 (see FIG. 2) of the periodic structure 3 with the phase mask device 10 within the scope of an overlay block 33.

Within the scope of the overlay block 33, the measurement radiation 7 can be influenced by the phase mask device 10 by virtue of the phase angle of the measurement radiation 7 within the optionally circular dual substructures 18 on the dual lattice 11 which is reciprocal to the target shape of the lattice 4 being offset by half a wavelength of the measurement radiation 7 vis-à-vis a complement of the dual substructures 18 on the phase mask device 10.

The optics system 8 and the camera device 9 are used in an imaging block 34.

Within the scope of the imaging block 34, an intensity pattern of the measurement radiation 7 on the camera device 9 can be ascertained by virtue of the measurement radiation 7 being imaged on the camera device 9 by the imaging device 17 following the overlay of the diffraction image 19 of the periodic structure 3 with the phase mask device 10.

Within the scope of the overlay block 33, the diffraction image 19 of the periodic structure 3 and the phase mask device 10 can be overlaid in the pupil plane of the Fourier device 12.

Within the scope of the imaging block 34, a plurality of interferograms can also be recorded, with the phase mask device 10 being displaced to another location in the pupil plane within the scope of the overlay block 33 for each interferogram.

Different wavelengths of the measurement radiation 7 can be used as part of the creation block 30, with the dual lattice 11 optionally being scaled within the scope of a scaling block 35 in a manner dependent on the employed wavelength of the measurement radiation 7.

Within the scope of the scaling block 35, the scaling of the dual lattice 11 can be brought about by changing the phase mask device 10.

As an alternative or in addition, the scaling of the dual lattice 11 within the scope of the scaling block 35 can be brought about by virtue of a focal length of the Fourier device 12 being varied by the zoom optical unit 12b.

In the process, a pupil size and/or an illumination region of the phase mask device 10 can be varied.

Within the scope of the deviation block 31, the component 2 can be additionally checked using a method for measuring an optically critical dimension, the intensity split of which is simulated with the aid of a parameterized model of the component 2.

Within the scope of the overlay block 33, the dual lattice 11 can be designed as a reciprocal of a one-dimensional and/or two-dimensional target shape of the lattice 4.

Further, in the case of the exemplary embodiment of the method depicted in FIG. 5, a NAND memory chip 20 (see FIG. 6) with periodically arranged through holes or vias 21 can be checked as component 2.

FIG. 6 shows a schematic illustration of a possible embodiment of a NAND memory chip 20 to be checked.

In FIG. 6, the component 2 to be checked by the above-described method and the above-described apparatus 1 is presently given by the NAND memory chip 20 to be checked. The periodic structure 3 is given by the vias 21.

In the example depicted in FIG. 6, the vias 21 are arranged on the lattice 4 and have a cross section representing the substructure 5. In the present example, the cross section representing the substructure 5 has a circular embodiment.

The NAND memory chip 20 depicted in FIG. 6 is realized in a 3-D construction by etching and/or coating periodically arranged vias 21 at deep, i.e. multiple bilayer stacks 22.

Using a suitable setting of the NA of the Fourier device 12, the vias 21 can be checked along their depth extent either in averaged fashion in the case of a small NA of the lens 14 or in sections in the case of a large NA.

FIGS. 1 and 2 each show a lithography system, for example a projection exposure apparatus 100, 200 for semiconductor lithography, having an illumination system 101, 201 with a radiation source 102 and an optical unit 103, 109, 206 which comprises at least one optical element 116, 118, 119, 120, 121, 122, Mi, 207. The apparatus 1 for checking a component 2, for example for checking the semiconductor component, is present in the projection exposure apparatuses 100, 200 depicted in FIGS. 1 and 2. In an alternative or in addition, the projection exposure apparatuses 100, 200 depicted in FIGS. 1 and 2 are configured to perform the method for checking the component 2, for example for checking the semiconductor component, described in the context of FIG. 5.

The disclosure can be suitable for the projection exposure apparatuses 100, 200 depicted in FIGS. 1 and 2, provided these are configured to produce and check a semiconductor component embodied as NAND memory chip 20 with the periodically arranged vias 21.

In the exemplary embodiments depicted in FIGS. 1 and 2, the apparatus 1 for checking the semiconductor component can be spatially separate from the location of the exposure of the semiconductor component. Further, the method for checking the semiconductor component to be produced by the projection exposure apparatuses 100, 200 in each case can be performed spatially separate from the location of the exposure of the semiconductor component.

In a possible embodiment, the optical units of the projection exposure apparatuses 100, 200 can also be incorporated in the apparatus 1.

### LIST OF REFERENCE SIGNS

1 Apparatus
2 Component
3 Periodic structure
4 Lattice
4a,b Lattice vector
5 Substructure
6 Measurement radiation source
6a Beam splitter device
7 Measurement radiation
8 Optics system
9 Camera device
10 Phase mask device
11 Dual lattice
11a,b Dual lattice vector
12 Fourier device
12a Arrow
12b Zoom optical unit
13 Arrangement device
14 Lens
15 Aperture stop
16 Holding device
17 Imaging device
18 Dual substructure
19 Diffraction image
20 NAND memory chip
21 Via
22 Bilayer stack
30 Creation block
31 Deviation block
32 Averaging block
33 Overlay block
34 Imaging block
35 Scaling block
100 EUV projection exposure apparatus
101 Illumination system
102 Radiation source
103 Illumination optical unit
104 Object field
105 Object plane
106 Reticle
107 Reticle holder
108 Reticle displacement drive
109 Projection optical unit
110 Image field
111 Image plane
112 Wafer
113 Wafer holder
114 Wafer displacement drive
115 EUV/used/illumination radiation
116 Collector
117 Intermediate focal plane
118 Deflection mirror
119 First facet mirror/field facet mirror
120 First facets/field facets
121 Second facet mirror/pupil facet mirror
122 Second facets/pupil facets
200 DUV projection exposure apparatus
201 Illumination system
202 Reticle stage
203 Reticle
204 Wafer
205 Wafer holder
206 Projection optical unit
207 Lens element
208 Mount
209 Lens housing
210 Projection beam
Mi Mirrors

1. An apparatus configured to check a component comprising a periodic structure, the periodic structure comprising substructures on a lattice, the apparatus comprising:
a measurement radiation source configured to provide measurement radiation;
an optics system;
a camera device; and
a phase mask device configured to influence at least one member selected from the group consisting of a phase angle of the measurement radiation and an amplitude of the measurement radiation,
wherein the phase mask comprises a dual lattice which is reciprocal to a target shape of the lattice of the periodic structure.

2. The apparatus of claim 1, wherein the phase mask device is configured to influence the phase angle of the measurement radiation.

3. The apparatus of claim 1, wherein the phase mask device is configured to influence both the phase angle and the amplitude of the measurement radiation.

4. The apparatus of claim 1, wherein the phase mask device is configured to influence the amplitude of the measurement radiation.

5. The apparatus of claim 1, wherein dual substructures are on the dual lattice.

6. The apparatus of claim 5, wherein the dual substructures are at least approximately circular.

7. The apparatus of claim 5, wherein the phase mask device is configured to bring about, away from the dual substructures, a phase offset of the measurement radiation of half a wavelength of the measurement radiation vis-à-vis a complement of the dual substructures.

8. The apparatus of claim 1, wherein the optics system comprises a Fourier device configured to perform an optical Fourier transform on the measurement radiation.

9. The apparatus of claim 8, further comprising an arrangement device configured to accommodate the component so the periodic structure is in an object plane of the Fourier device.

10. The apparatus of claim 9, wherein the phase mask device is in a pupil plane of the Fourier device which is reciprocal to the object plane.

11. The apparatus of claim 9, wherein the Fourier device comprises a lens, and wherein the Fourier device has:
a numerical aperture to check the entire periodic structure perpendicular to the object plane; or
a numerical aperture to check only a sectional region of the periodic structure parallel to the object plane.

12. (canceled)

13. (canceled)

14. The apparatus of claim 8, wherein the the Fourier device comprises a zoom optical unit.

15. The apparatus of claim 1, wherein the phase mask device comprises:
a transmissive substrate; and
etched structured half wavelength coating supported by the transmissive substrate.

16. The apparatus of claim 1, wherein the phase mask device is configured to be digitally actuatable and/or transmissive and/or reflective and/or as a microelectronic mechanical system and/or as a spatial light modulator.

17. The apparatus of claim 1, further comprising an imaging device configured to image the measurement radiation onto the camera device.

18. The apparatus of claim 1, wherein:
the measurement radiation source is configured to create measurement radiation at different wavelengths; and/or
the measurement radiation is infrared radiation.

19. The apparatus of claim 1, wherein dual lattice is a reciprocal of a one-dimensional and/or two-dimensional target shape of the lattice.

20. A method, comprising:
using the apparatus of claim 1 to check the component.

21. A method of checking a component comprising a periodic structure, the periodic structure comprising substructures on a lattice, the method comprising:
ascertaining a respective deviation of the substructures from a reference substructure by interferometry.

22.-32. (canceled)

33. A system, comprising:
an illumination system comprising a radiation source and an optical unit comprising an optical element; and
an apparatus according to claim 1,
wherein the system comprises a lithography system.

34. (canceled)

35. (canceled)
